(19) United States
(12) Patent Application Publication
(10) Pub. No.: US 2009/0302862 A1
(43) Pub. Date: Dec. 10, 2009

(54) METHOD AND SYSTEM FOR MONITORING PARTIAL DISCHARGE WITHIN AN ELECTRIC GENERATOR

(75) Inventor: Michael Twerdochlib, Oviedo, FL (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: SIEMENS POWER GENERATION, INC., Orlando, FL (US)

(21) Appl. No.: 12/132,708

(22) Filed: Jun. 4, 2008

(51) Int. Cl. H01H 31/12; G01R 31/12

(52) U.S. Cl. 324/551; 324/536

(57) ABSTRACT

Electrical generators used for power generation typically operate at high voltage. The High operating voltage results in a severe electrical stress environment for the generator conductor insulation system. The high electrical stress cal lead to a phenomena such as corona, partial discharge and arcing that can cause damage to the insulation and conductors. Disclosed is a novel method and system of detecting partial discharge activity within an electric generator. The method employs at least two Rogowski loops non-contactingly surrounding individual iso-phase bus conductors, where the loops are wired in differential mode to detect fast moving electrical pulses indicative of partial discharge.

### FIELD OF THE INVENTION

The present invention provides a method and system for monitoring partial discharge activity, and more particularly a method and system for monitoring partial discharge activity in an electric generator of an electric power production facility by detecting electrical pulses in conductors proximal the generator.

### BACKGROUND

Electric generators used for power generation are typically operate at high voltage, generally above 14 kV. The generators comprise insulated conductors typically referred to as stator coils and are arranged in three electrically isolated phases. The three phases of stator coils are then electrically connected to the power distribution network via electrically isolated phase conductors, or iso-phase bus bars.

The high operating voltage of the generator results in severe electrical stress induced on the insulating systems that electrically isolate the conductors of the generator. The high electrical stress environment surrounding the electrical conductors can lead to phenomena such as corona, partial discharge (PD) and arcing Resulting charge migration and buildup results in discharges both in and within weakened spots of the coil ground wall insulation. Free radical chemical species may be produced that attack the insulation, thus accelerating the rate of partial discharge and deterioration of the insulation and ultimately failure of the stator coils and eventually the generator.

### SUMMARY OF THE INVENTION

The present invention provides a method and system for monitoring partial discharge activity, and more particularly a method and system for monitoring partial discharge activity in an electric generator of an electric power production facility by detecting electrical transients in conductors proximal the generator. Furthermore, the electrical transients are detected in a non-contacting manner via an inexpensive and simple to construct and implement method and system.

One aspect of the invention involves a method of monitoring PD activity in an electric iso-phase bus by arranging a first high frequency electrical sensor at least partially circumferentially surrounding a first conductor of the bus where the first sensor has an input lead and an output lead, arranging a second high frequency electrical sensor at a distance from the first sensor relative to an axial direction of the bus, at least partially circumferentially surrounding the first conductor of the bus where the second sensor has an input lead and an output lead, differentially connecting the first and second sensors to operate in a differential mode where the first output lead of the first sensor is connected to the output lead of the second sensor, electrically coupling the input leads of the first and second sensors to an electrical measurement device, measuring a sensor voltage by the measuring device where the voltage is induced in the first sensor and the second sensor by a current flow of the iso-phase bus, and monitoring the first and second measured voltages for a transient voltage pulse, where the monitoring device determines if the transient voltage pulse is the result of partial discharge activity of a specific electric generator connected to the bus. The method described above may further include the first and second sensors substantially surrounding a first conductor of the bus. The method described above may also further include the first sensor comprising a plurality of first sensor segments and the first sensor segments may further be electrically connected in series to form a loop. The method described above may also further include the second sensor comprising a plurality of second sensor segments and the second sensor segments may be electrically connected in series to form a loop. The method described above may further include the first and second sensors arranged substantially perpendicular and coaxially with the bus. The second sensor can advantageously be arranged between 2 and 10 meters from the first sensor with respect to an axial direction of the bus. Also, the first and second sensors specifically can be Rogowski loops. Furthermore, the first and second sensors advantageously may not be in physical contact with the bus and may be directly coupled to the electrical measurement device. The duration of the transient voltage pulse is 10 nanoseconds or less in duration and 10 nanoamps or less in magnitude.

Another aspect of the invention is a non-contact iso-phase bus partial discharge monitoring system that includes a sensor arranged coaxially surrounding and spaced from a conductor of the bus that is formed from an insulated wire having a first wire end and a second wire end opposite the first end, and is wrapped around a common axis to form a plurality of closed loops where the first and second ends form leads of the sensor, an electrical measurement device electrically connected to the sensor leads that measures a voltage of the sensor, where the sensor voltage is proportional to a current of the bus, and a monitoring device that monitors the sensor voltage for high frequency transient electrical pulses.

Another aspect of the invention is a high voltage inductive iso-phase bus current monitoring system that includes an inductive non-contact sensor having a first sensor lead and a second sensor lead arranged coaxially around a conductor of a phase of the bus, an electrical input device electrically connected with the first and second sensor leads, and an evaluation unit that receives an output of the electrical input device and monitors an operating condition of the iso-phase bus for the presence of partial discharge.

### BRIEF DESCRIPTION OF THE DRAWINGS

The above-mentioned and other concepts of the present invention will now be described with reference to the drawings of a preferred embodiment of the present invention of a method and system for monitoring partial discharge activity. The illustrated embodiments of the method and system for monitoring partial discharge activity are intended to illustrate, but not limit the invention. The drawings contain the following figures:

FIG. 1 is a system layout of a power generation facility;

FIG. 2 is a cut away view of an iso-phase bus of the power generation facility having a first and a second Rogowski Loop wired in differential mode;

FIG. 3 is a top view of a Rogowski Loop;

FIG. 4 is a side view of the Rogowslki Loop;

FIG. 5 is a section view of the Rogowski Loop;

FIG. 6 is a time plot of the individual out-put signals of a first and second Rogowski Loop due to a steady-state alternating electrical current of the iso-phase bus;

FIG. 7 is a time plot of the individual out-put signals of a first and second Rogowski Loop due to a fast moving electrical transient of the iso-phase bus;

FIG. 8 is a top view of a segmented Rogowski Loop.

### DETAILED DESCRIPTION OF THE INVENTION

The invention described herein employs one or more basic concepts. For example, one concept relates to a method of continuously and non-contactingly monitoring the electrical output of inductively coupled loops or coils for electrical transients that indicate the presence of partial discharge. A benefit of the non-contacting nature of the present invention is reduced installation requirements and associated costs compared to a contacting method and system. Another concept employs use of Rogowski loops arranged surrounding an electrically isolated conductor of a power generation installation to inductively determine the presence of partial discharge in an electric device connected to the conductor.

The present invention is disclosed in context of use of monitoring PD within an electric generator of an electric power production facility. The principles of the present invention, however, are not limited to use with an electric generator or within an electricity power production facility. For example, the methods and/or systems could be used within the aerospace, transportation or manufacturing industries or any other area where high voltages are generated or used. For another example, the methods and/or systems could be used within high voltage electrical devices such as an industrial motor, transformer or electric furnace. One skilled in the art may find additional applications for the methods, systems, apparatus, and configurations disclosed herein. Thus the illustration and description of the present invention in context of the exemplary electric power production facility for monitoring partial discharge within an electric generator is merely one possible application of the present invention. However the present invention has particular applicability for use as a sensing system for monitoring partial discharge within an electric generator.

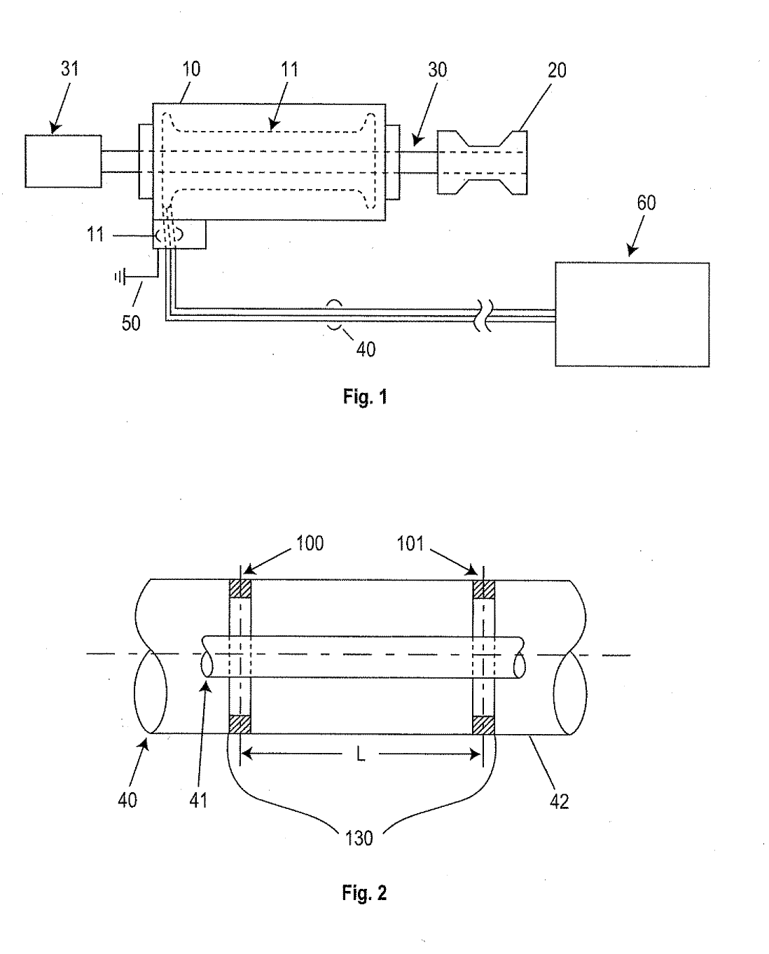

An overview of the invention is provided below followed by a more detailed explanation. Referring to FIGS. 1 and 2, a power generation installation typically comprises an electric generator 10 connected between a turbine 20 and an exciter 31. The electric generator comprises electric conductors known as coils 11. The coils 11 are electrically connected to other electrical conductors of the power generation installation 40 which operatively conducts the induced current through the power generation installation for distribution to an associated electrical power distribution network 60. A Rogowski Loop 100 is arranged surrounding each electrical conductor of the power generation installation 40 to detect the presence of a fast moving, high frequency, electrical transient traveling in the power generation installation conductor 40 resulting from PD activity within the electric generator 10.

### Components

Still referring to FIGS. 1 and 2, the generator 10 has a rotor 30 rotated by the turbine 20. The rotor 30 contains electrical rotor conductors 21 electrically connected to a direct current source 31 that provides a direct current in the rotor conductors 21. The provided current in the rotor conductors 21 creates a magnetic field of variable strength proportional to the magnitude of the provided current. The rotor 30 operatively rotates while producing the aforementioned magnetic field. The rotating magnetic field induces an alternating current in the coils 11 wound within the generator. The coil ends opposite the distribution network 60 side are shorted together and electrically grounded to earth 50.

The coils 11 are electrically connected into phase groups that are then connected to the electrically isolated phase conductors 41. The isolated phase conductors 41 operatively conduct the induced current of each phase group to the electrical power distribution network 60. Each electrically isolated phase conductor 41 has an associated electrical shield 42 that electrically isolates each phase from an other phase or the surrounding equipment of the power production facility.

At least one iso-phase bus 40 is associated with a generator 10. The iso-phase conductor 41 can be made of any conductive material, but preferably is made of a low resistance material such as copper, and more preferably oxygen free copper. The electrical shield 42 can be made of any conductive material, but preferably is made of an inexpensive conductive material such as aluminum.

The iso-phase conductor 41 and electrical shield 42 generate heat during generator 10 operation due to the flow of current in the respective materials. Therefore, the bus 40 typically requires cooling to prevent overheating. The cooling medium typically is a fluid and preferably a gas. More preferably, the cooling gas is hydrogen or air. When a hydrogen gas cooling medium is employed, there exists the possibility of an explosion of the hydrogen gas. Sufficient measures are required to ensure that an explosive mixture of hydrogen and oxygen does not occur. To properly protect personnel and equipment from harm, an explosion proof pressure vessel type enclosure is required to enclose the bus. Preferably, the bus shield and the enclosure are integrated into a unitary enclosure. However, the previously mentioned issues are avoided when the cooling medium is air.

A Rogowski loop 100 or 101, when placed around a current carrying conductor such as an iso-phase bus conductor 41 as seen in FIG. 2, develops a voltage across its two leads 130 dependant on and proportional to the following parameters:

N=number of turns per inch

A=mandrel former cross-section

Θ=angle that the loop surrounds center conductor (typically Θ=2π)

dI/dt=rate of change of current in center conductor

The following features of the Rogowski loop have no effect on the output voltage of the loop:
1) mandrel diameter, Dₘ
2) distortion of loop shape (not perfectly circular), and
3) perpendicularity of loop relative to center conductor.

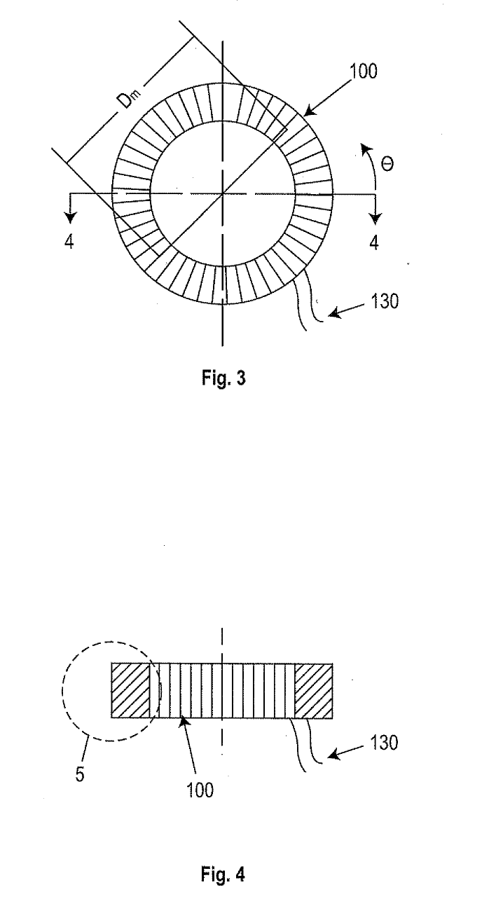

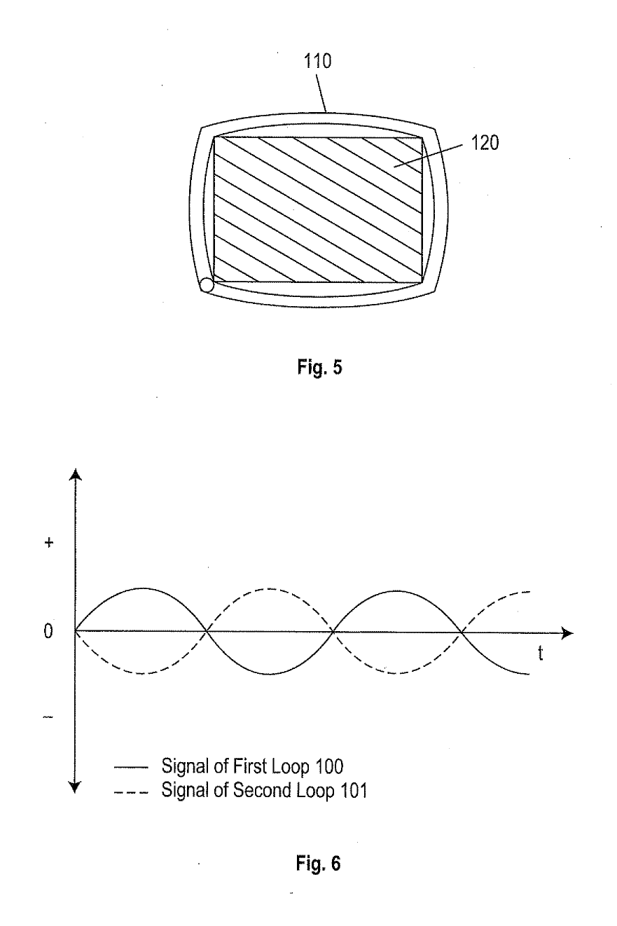

FIGS. 3, 4 and 5 show a Rogowski loop 100 having an insulated conductive wire 110 wound around a pliable, non-magnetically permeable mandrel former 120 such as are commercially available. The insulated conductor wire 110 may be made of any conductive material but preferably one that has a low electrical resistance such as copper. The ends of the wire form leads 130 for electrically connecting the Loop 100 to an electrical device such as a voltage measurement device.

The cross-sectional shape of the pliable, non-magnetically permeable mandrel former will define the cross-sectional shape of the Rogowski loop, as seen in FIGS. 2, 4 and 5. Any practical cross-sectional shape can be used for the former cross-section such as, but not limited to, circular, oval, rectangular and square. A square, or preferably a rectangular, pliable mandrel former cross-section as seen in FIGS. 2, 4 and 5 maximizes the mandrel former cross-section while minimizing the loop's intrusion into the shield 42 enclosure.

The Rogowski loops 100, 101 are highly sensitive to rapid changes in current of a conductor surrounded by the loop, such as fast moving pulses associated with PD. Therefore, the loops 100, 101 measure transients in the current of the phase conductor 41 such as high-speed current pulses that originate from PD activity within the electric generator 10.

FIG. 2 shows two Rogowski loops 100, 101 mounted to the inside diameter surface of the iso-phase bus shield 42 of a power generation facility. The loops 100, 101 non-contactingly surrounding the center conductor 41 of the phase bus 40 of the power generation facility and are separated from each other by a distance L. The loops 100, 101 may be mounted at any convenient point along the path of the iso-phase bus between the generator in question and any equipment subsequently attached to the bus like a transformer or other device. Preferably, the loops 100, 101 are mounted as close to the generator as is practical to reduce the likelihood of a false determination of generator PD activity.

The loops 100, 101 are securely mounted to the bus shield 42 to ensure that the loops do not contact the conductor 41. Preferably, the loops 100, 101 are mounted via a non-electrically conductive manner, more preferably via an insulating material (not shown) such as a non-conducting fiberglass block or fabric and an adhesive such as a resin. One skilled in the art of high power electrical measurement and instrumentation will readily appreciate the various appropriate methods of mounting the Rogowski loops 100, 101.

In an alternate embodiment, the loops 100, 101 can be mounted on the outside of the iso-phase bus shield. When the bus is cooled by hydrogen gas, mounting the loops on the outside of the iso-phase bus shield 42 or within a flange used to connect shield sections, where such construction is employed are preferred to simplify installation and ease of access of the loops 100, 101 and to avoid the explosion issues discussed above associated with the use of hydrogen gas. However, it is understood that mounting the loops 100, 101 on the outside of the bus shield 42 can result in a significantly diminished signal strength due to an associated attenuation of field strength of the bus conductor 41. In a further alternate embodiment, a single Rogowski Loop 100 can be used. The single Loop 100 can be mounted on either the inside or the outside of the bus shield 42 in a manner as discussed above.

As discussed above, the angle, Θ, that the loop 100 and/or 101 encloses the center conductor influences the measured loop output voltage at the loop leads 130, where the lead voltage is proportional to the angle, Θ, that the loop encloses around the center conductor 41. Therefore, the loops 100, 101 preferably enclose a full 360° circle or more to maximize the output signal. However, the Rogowski loops 100, 101 can be a partial loop that comprises less than a full 360° circle.

Furthermore, each loop 100, 101 may be segmented into two or more segments 105 as seen in FIG. 8. For example, a complete 360° closed loop can be divided into as many segments as desired and then wired in series to form a complete loop. Segmenting the loop may simplify the installation of the loop 100, 101 around the bus conductor 41 as the conductor 41 does not have to be disassembled to accommodate the loop 100, 101. Also, if the loop 100, 101 is installed inside the bus shield 42, the smaller segments 105 easily pass through an access port (not shown) in the bus shield 42 avoiding the need for further dismantling of the shield 42. Also, each individual segment 105 may be of a different arc length. The total enclosed angle Θ of the resulting loop 100, 101 is the sum of the individual arc angles of all of the individual segments 105 that comprise the resulting loop 100, 101, once the individual segments are wired in series. Furthermore, multiple loops may be employed for increased signal sensitivity.

### Operation

Partial discharge produces a small amplitude in the order of 10's of nano-amps, and short duration, in the order of 10's of nano-seconds, electrical pulse. The PD pulse propagates along conductors away from the point of origin. In the case of a high voltage electrical generator, PD typically originates in the electrical windings 11 and propagates along conductors 41 connected to the windings. The presence of PD within the generator 10 is detected in various ways. The present invention identifies the presence of PD activity within the generator 10 through detection of electrical pulses traveling in the conductors 41.

Due to complexities associated with the generator 10 and its operation, such as the high magnetic flux, high voltage environment and possibly explosive hydrogen environment within the generator, it is preferred to detect generator PD activity from outside the generator 10. PD that initiates within the generator 10 causes an electrical pulse to propagates through the generator coils 11 and along the iso-phase bus 40 away from the point of initiation.

It is preferable to not merely detect an electrical pulse in the iso-phase bus 40 but also determine that the detected electrical pulse is emanating from the generator in question and not from other equipment connected along the power distribution network or from electrical activity elsewhere in the power generation installation.

As discussed above, FIG. 2 shows two Rogowski loops 100, 101. The Rogowski loops 100, 101 measure transients in the current of the phase conductor 41 such as high-speed current pulses that originate from PD activity within the electric generator 10. The direction in which the pulse is traveling, either toward or away from the generator 10, is then determined by using two pairs of loops 100, 101, where each loop of a pair is spaced between one to two meters apart and the pairs are spaced approximately 10 meters apart, is used to identify the pulse direction by determining which of the two pairs of loops, 100, 101, register the pulse first. All pulses traveling away from the generator 10 are deemed to originate within the generator 10 and thus identified as generator PD activity. Furthermore, lead length between the loops 130 and any measurement device need to be equal in order to cancel any differential time propagation effects.

Typically, the steady state alternating current output of the generator that flows in a phase conductor (50 Hz or 60 Hz) is on the order of 10 kA to 20 kA, however this typical range is not a limiting aspect of the present invention and the invention is operable at ranges outside 10 kA to 20 kA. In order to detect PD activity, the component of the measurement signal generated by the Rogowski loop attributed to the generator steady state output would need to be eliminated.

One way to eliminate the measurement signal component attributed to the generator steady state output is to high-pass-filter or band-pass filter the measurement signal to eliminate the low frequency, 50 Hz or 60 Hz, steady state component. One of ordinary skill in the art of data acquisition will readily appreciate understand the requirements and proper procedures necessary to filter the 50 Hz or 60 Hz, steady state component from the measurement signal.

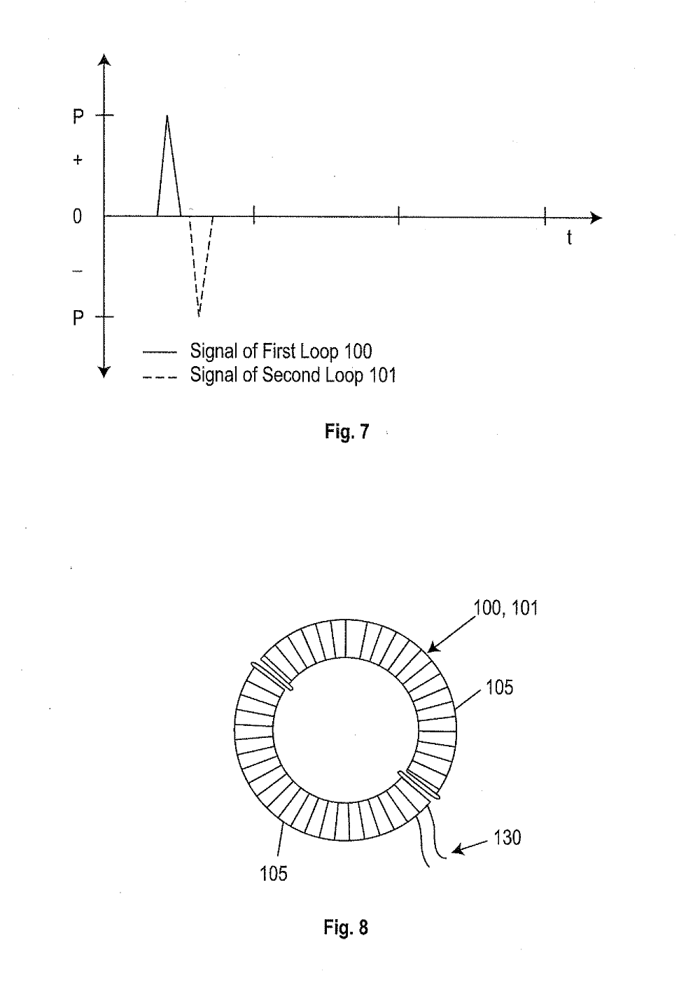

A preferred technique to eliminate the steady state component of the measurement signal would be to connect the positive lead 130 of the one of the two Rogowski loops 100, 101 directly to the negative lead of the other loop 101, 100 and then the remaining leads are connected to the electrical measurement device. Connecting the leads in this manner is known as differential mode. In differential mode, the loop output signals due to the generator 10 steady state current are opposite in polarity. For a 60 Hz generator, the 60 Hz output signal has a 3,300 km wavelength. FIG. 6 illustrates the signals of the two loops 100, 101 spaced a distance of approximately 2 meters to 10 meters apart, 2 m<L>10 m, the signals are essentially equal in magnitude but opposite in sign due to the extremely long wavelength and therefore the signal values essentially cancel each other, that is, they sample the same 60 Hz current. FIG. 7 illustrates the loops 100, 101 output when a fast moving electrical transient attributed to PD which has an extremely short wave length passes. The fast moving signals will be time shifted do to the 2 to 10 meter spacing of the two loops 100, 101 from each other and the signals magnitude will combine together instead of canceling. For example, a 10 nanoamp, 10 nanosecond PD pulse would produce a 1 volt response using two Rogowski loops wired in differential mode, as in FIG. 2, where each loop has a rectangular cross-section of 0.5 in.×1.0 in. and utilizing 33 turns per inch. This method produces an easily measurable signal using a commonly available electrical measurement device and avoids the need to filter the loop measurement signal as discussed above.

1. A method of monitoring partial discharge in an electric iso-phase bus, comprising:
arranging a first high frequency electrical sensor at least partially circumferentially surrounding a first conductor of the bus, wherein the first sensor has an input lead and an output lead;
arranging a second high frequency electrical sensor at a distance from the first sensor relative to an axial direction of the bus, at least partially circumferentially surrounding the first conductor of the bus, wherein the second sensor has an input lead and an output lead;
differentially connecting the first and second sensors to operate in a differential mode, wherein the output lead of the first sensor is connected to the output lead of the second sensor;
electrically coupling the input leads of the first and second sensors to an electrical measurement device;
measuring a sensor voltage by the measuring device where the voltage is induced in the first and the second sensors by a current flow of the iso-phase bus; and
monitoring the first and second measured voltages by a monitoring device for a transient voltage pulse, wherein the monitoring device determines if the transient voltage pulse is the result of partial discharge activity of a specific electric generator connected to the bus.

2. The method as claimed in claim 1, wherein the first and second sensors substantially surround a first conductor of the bus.

3. The method as claimed in claim 1, wherein the first sensor comprises a plurality of first sensor segments electrically connected in series to form a loop.

4. The method as claimed in claim 1, wherein the second sensor comprises a plurality of second sensor segments electrically connected in series to form a loop.

5. The method as claimed in claim 1, wherein the first and second sensors are arranged substantially perpendicular and coaxial with the bus.

6. The method as claimed in claim 1, wherein the second sensor is arranged between 1 and 2 meters from the first sensor with respect to an axial direction of the bus.

7. The method as claimed in claim 6, further comprising a further first high frequency electrical sensor and a further second high frequency electrical sensor where the further set of sensors are axially spaced 10 meters from the original set of sensors with respect to an axial direction of the bus.

8. The method as claimed in claim 1 wherein the first and second sensors are Rogowski loops.

9. The method as claimed in claim 1, wherein the first and second sensors are not in physical contact with the bus.

10. The method as claimed in claim 1, wherein the first and second sensors are physically coupled to the electrical measurement device.

11. The method as claimed in claim 1, wherein the electrical measurement device is monitoring the measurement signal for a transient voltage pulse of 10 nanoseconds or less in duration and 10 nanoamps or less in magnitude.

12. A non-contact iso-phase bus partial discharge monitoring system, comprising:
a sensor arranged coaxially surrounding and spaced from a conductor of the bus:
formed from an insulated wire having a first wire end and a second wire end opposite the first end, and
wrapped around a common axis to form a plurality of closed loops where the first and second ends form leads of the sensor;
an electrical measurement device electrically connected to the sensor leads that measures a voltage of the sensor, where the sensor voltage is proportional to a rate of change of the current of the bus; and
a monitoring device that monitors the sensor voltage for high frequency transient electrical pulses.

13. The system as claimed in claim 12, wherein the sensor comprises a first Rogowski loop and a second Rogowski loop electrically connected to operate in differential mode.

14. The system as claimed in claim 13, wherein the first Rogowski loop comprises a plurality of first loop segments wired in series to form a first loop and the second Rogowski loop comprises a plurality of second loop segments wired in series to form a second loop.

15. The system as claimed in claim 14, wherein the first and second Rogowski loop's are axially arranged 1 to 2 meters apart with respect to an axial direction of the bus.

16. The system as claimed in claim 12, further comprising a further sensor where the sensor and the further sensor are axially spaced 10 meters from the original sensor with respect to an axial direction of the bus.

17. The system as claimed in claim 16, wherein the further sensor comprises a first further Rogowski loop and a second further Rogowski loop electrically connected to operate in differential mode and axially arranged 1 to 2 meters apart with respect to an axial direction of the bus.

18. An inductive high voltage iso-phase bus current monitoring system, comprising:
an inductive non-contact sensor having a first sensor lead and a second sensor lead arranged coaxially around a conductor of a phase of the bus;
an electrical input device electrically connected with the first and second sensor leads; and
an evaluation unit that receives an output of the electrical input device and monitors an operating condition of the iso-phase bus for the presence of partial discharge.

19. The system as claimed in claim 18, wherein the sensor comprises a first loop and a second loop where the second loop is arranged between 1 and 2 meters from the first loop with respect to an axial direction of the bus and the first and second loops are electrically connected to operate in differential mode.

20. The system as claimed in claim 19, further comprising an additional inductive non-contact sensor where the sensor and the additional sensor are axially spaced 10 meters apart and the additional sensor comprises a first additional Rogowski loop and a second additional Rogowski loop electrically connected to operate in differential mode axially arranged 1 to 2 meters apart with respect to an axial direction of the bus.
